(19) United States
(12) Patent Application Publication
(10) Pub. No.: US 2004/0192053 A1
(43) Pub. Date: Sep. 30, 2004

(54) Etching method and apparatus

(75) Inventor: Kiwamu Fujimoto, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/813,079

(22) Filed: Mar. 31, 2004

(30) Foreign Application Priority Data
Mar. 31, 2003 (JP) 2003-095946
Mar. 3, 2004 (JP) 2004-059674

(51) Int. Cl. H01L 21/311; H01L 21/302; H01L 21/461

(52) U.S. Cl. 438/697

(57) ABSTRACT

In an etching method and apparatus, a plasma etching is performed on an etching target film formed on an object to be processed in a processing chamber by generating a plasma of a processing gas introduced into the airtight processing chamber. A resist including an alicyclic acrylate resin and/or an alicyclic methacrylate resin is used as a mask and wherein the plasma etching is performed while maintaining a surface temperature of the object at about 20° C. or less.

### FIELD OF THE INVENTION

The present invention relates to an etching method and apparatus for performing an etching process by using a plasma of a processing gas; and, more particularly, to an etching method and apparatus for performing an etching process on a film to be processed by using a resist including an alicyclic acrylate resin and/or an alicyclic methacrylate resin as a mask.

### BACKGROUND OF THE INVENTION

There are various techniques for performing an etching on an etching target film formed on, e.g., a semiconductor wafer (hereinafter, referred to as “wafer”), by using a plasma of a processing gas introduced into a processing chamber. For example, Japanese Patent Laid-open Publication No. 1993-152255 discloses therein a technique for etching an oxide film formed on a wafer by employing a CF-based gas or the like as a processing gas.

In case of etching such an etching target film formed on a wafer, a resist such as a photoresist or the like is used as a mask. Especially, widely used recently to cope with ever increasing demands for a micro patterning is an ArF photoresist or a F₂ photoresist appropriate for forming a fine opening pattern smaller than or equal to about 0.13 μm, which is exposed to a laser beam using an ArF gas or a F₂ gas as a radiation source.

Since, however, such as an ArF photoresist film has a low plasma resistance, to thereby suffer from a problem that a surface thereof becomes roughened during an etching process. If the surface of the photoresist film becomes rough, a shape of an opening is changed as the etching progresses and, resultantly, a designed shape may not be formed properly by the etching.

It may be preferable to performe an etching by employing a processing gas capable of reaction by-products which can be easily adhered to a surface of a resist film. The reaction by-products adhered to the surface thereof serves as a protective layer, so that the plasma resistance of the resist film can be increased (see, e.g., the Japanese reference supra).

However, in case of using a resist film including an alicyclic acrylate resin and/or an alicyclic methacrylate resin such as an ArF photoresist film, oxygen is generated from the resist film by a plasma of a processing gas, depending on the types of the processing gases. The oxygen thus generated reacts with plasma radicals at the surface of the resist film and then are discharged, so that the reaction by-products serving as the protective layer is not adhered to such surface portions of the resist. Accordingly, as the etching progresses, such portions to which the reaction by-products are not adhered are sputtered, so that parts of the photoresist film may be completely removed during the etching process. Thus, unintended parts can be etched and vertically-striped cutouts (striations, for example, are formed on inner surfaces of holes formed by the etching. If such striations are formed, an actual gap between the holes formed by the etching is narrowed, thereby causing drawbacks such as shorts or the like.

### SUMMARY OF THE INVENTION

It is, therefore, an object of the present invention is to provide an etching method and apparatus capable of avoiding a generation of surface roughness or striations while performing an etching process by using a resist film including an alicyclic acrylate resin and/or an alicyclic methacrylate resin as a mask.

In accordance with one aspect of the invention, there is provided an etching method for performing a plasma etching process on an etching target film formed on an object to be processed in an airtight processing chamber by generating a plasma of a processing gas introduced into the processing chamber by using a resist as a mask, the resist including an alicyclic acrylate resin, an alicyclic methacrylate resin, or a combination thereof, wherein the plasma etching process is performed while maintaining a surface temperature of the object under a temperature condition of about 20° C. or less.

In accordance with another aspect of the present invention, there is provided an etching apparatus for performing a plasma etching process on an etching target film formed on an object to be processed in an airtight processing chamber by generating a plasma of a processing gas introduced into the processing chamber by using a resist as a mask, the resist including an alicyclic acrylate resin, an alicyclic methacrylate resin, or a combination thereof, wherein the plasma etching process is performed while maintaining a surface temperature of the object under a temperature condition of about 20° C. or less.

In the present invention, the plasma etching process may be performed while maintaining a surface temperature of the object under a temperature condition of about 0° C. or less; the etching target film may be a low-k insulating film containing silicon (Si), oxygen (O) and carbon (C) atoms.

In the present invetion, the surface temperature of the object to be processed may be lowered by using a heat dissipation mechanism; the heat dissipation mechanism may include a cooling unit for cooling the object to be processed by a coolant, and the surface temperature of the object to be processed is controlled at about 20° C. or less by lowering a temperature of the coolant.

In the present invention, the heat dissipation mechanism may include an adsorptive holding unit for adsorptively holding the object to be processed, and the surface temperature of the object to be processed is lowered by enhancing an adsorptive power of the adsorptive holding unit; the adsorptive power may be enhanced by finishing a surface of the object to be processed to be of a mirror surface, the surface being in contact with the adsorptive holding unit.

In the present invetion, in case of employing a Johnson-Rahbek type adsorptive holding unit, the adsorptive power may enhanced by adopting a material of the adsorptive holding unit to allow an amount of leakage current flowing therethrough to be controlled under the temperature condition.

In the present invention, the surface temperature of the object may lowered by a heat sink mechanism; surface temperature lowering of the object by the heat sink mechanism may be carried out by controlling a high frequency power applied to an electrode disposed in the processing chamber to generate a plasma and a pressure of a backgas supplied to a backside of the object.

Further, as used in this specification, 1 mTorr and 1 sccm correspond to (1×10⁻³×101325/760) Pa and (1×10⁻⁶/60) m³/sec, respectively.

### BRIEF DESCRIPTION OF THE DRAWINGS

The above and other objects and features of the present invention will become apparent from the following description of preferred embodiments, given in conjunction with the accompanying drawings, in which:

FIG. 1 is a schematic cross sectional view of an etching apparatus in accordance with a first preferred embodiment of the present invention;

FIG. 2 illustrates a cross sectional view of a film structure on which an etching process is performed in the first preferred embodiment;

FIG. 3 provides a relationship between a temperature of a coolant supplied to a temperature control medium container and a surface temperature of a wafer in the first preferred embodiment;

FIGS. 4A and 4B describe an experimental results obtained by performing an etching process by setting a coolant temperature (a temperature of a lower electrode) at 25° C., wherein FIG. 4A shows a conventional state of a top surface of a resist and FIG. 4B presents a conventional state of a top surface of a silicon oxide film after removing a resist film and an antireflection film by ashing or the like;

FIG. 5 represents a schematic diagram for explaining conventional striations;

FIGS. 6A and 6B substantially explain causes of the striations;

FIGS. 7A and 7B depict experimental results obtained by performing an etching process by setting a temperature of the coolant (a temperature of the lower electrode) at −20° C., wherein FIG. 7A shows a state of the top surface of the resist and FIG. 7B illustrates a state of the top surface of the silicon oxide film after removing the resist film and the anti-reflecting coating film by ashing or the like; and

FIG. 8 offers a distribution of a surface temperature of a wafer in case of varying a second high frequency power applied to the lower electrode and a back gas pressure.

### DETAILED DESCRIPTION OF THE PREFERRED EMBODIMENTS

Hereinafter, an apparatus in accordance with preferred embodiments of the present invention will be described in detail with reference to the accompanying drawings. Further, in this specification and the accompanying drawings, like reference numerals will be given to like parts having substantially same functions, and redundant description thereof will be omitted.

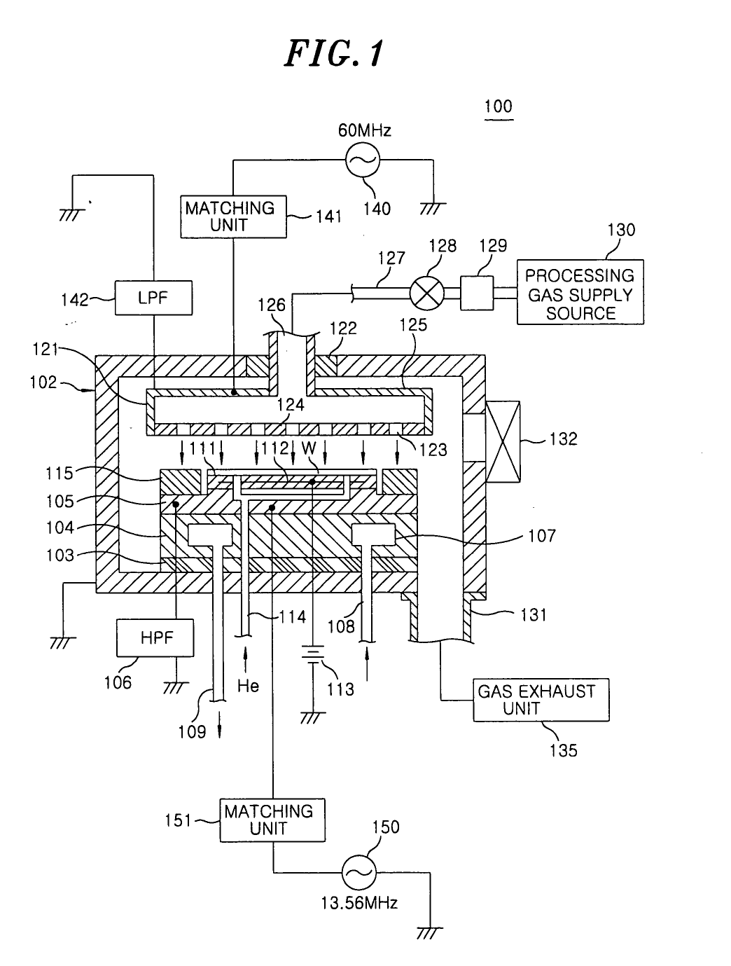

Referring to FIG. 1, there is illustrated a schematic configuration of an etching apparatus in accordance with the first embodiment of the present invention. The etching apparatus 100 is structured such that an upper and a lower electrode plate are positioned to face each other in parallel and are connected to respective plasma generating power supplies. The etching apparatus 100 is so-called a capacitively coupled parallel plate type etching apparatus.

The etching apparatus 100 includes a cylindrical processing chamber 102 made of aluminum whose surface is anodized (alumited), the processing chamber 102 being grounded. A substantially columnar susceptor supporting table 104 is installed on a bottom of the processing chamber 102 via an insulating plate 103 made of, e.g., ceramic. Further, a susceptor 105 acting as a lower electrode is provided on the susceptor supporting table 104. The susceptor 105 is connected to a high pass filter (HPF) 106.

A temperature control medium channel 107 is provided in the susceptor supporting table 104. A temperature control medium is fed through an inlet line 108 into the temperature control medium channel 107. The temperature control medium circulates along the temperature control medium channel 107, and is then exhausted through an outlet line 109. The circulation of the temperature control medium allows a temperature of the susceptor 105 to be controlled at a desired level.

Further, the susceptor 105 is provided with a disk-shaped protrusion at its upper central portion, and an adsorptive holding unit, e.g., an electrostatic chuck 111 having almost the same shape as the wafer W is provided thereon. The electrostatic chuck 111 is structured such that an electrode 112 is embedded in an insulating material. When a DC voltage of, e.g., 1.5 kV is applied to the electrode 112 from a DC power supply 113 connected thereto, the wafer W is electrostatically adsorbed to the electrostatic chuck 111 by an electrostatic force.

A gas channel 114 for supplying a heat transfer medium (for example, backside gas such as a He gas) to a backside of the wafer W is formed through the insulating plate 103, the susceptor supporting table 104, the susceptor 105, and the electrostatic chuck 111. Therefore, heat transfer is carried out between the susceptor 105 and the wafer W via the heat transfer medium, thereby having the wafer W to be maintained at a predetermined temperature.

An annular focus ring 115 is arranged on an upper peripheral portion of the susceptor 105 in such a way that the focus ring 115 surrounds the wafer W placed on the electrostatic chuck 111. The focus ring 115 is formed of an insulating material such as ceramic or quartz, or a conductive material, and functions to enhance an etching uniformity.

An upper electrode 121 is installed above the susceptor 105 in such a way that they are positioned to face each other in parallel. The upper electrode 121 is supported within the processing chamber 102 through an insulating member 122. The upper electrode 121 is comprised of an electrode plate 124 facing the susceptor 105 and having a plurality of injection openings 123 formed therethrough, and an electrode supporting member 125 supporting the electrode plate 124. The electrode plate 124 is formed of, e.g., quartz, and the electrode supporting member 125 is made of a conductive material, e.g., aluminum whose surface is alumited. Furthermore, the distance between the susceptor 105 and the upper electrode 121 is configured to be adjustable.

A gas inlet 126 is provided at the center of an upper part of the electrode supporting member 125 of the upper electrode 121, and is connected to a gas supply line 127 which is in turn connected through a valve 128 and a mass flow controller 129 to a processing gas supply source 130.

An etching gas, to be used in a plasma-etching process, is supplied from the processing gas supply source 130. Even though only one process gas supplying system including the processing gas supply source 130 and so on is depicted in FIG. 1, a number of processing gas supply systems may be provided to independently control respective flow rates of gases, such as C₄F₆, Ar and O₂, and supply the gases into the processing chamber 102.

Meanwhile, an exhaust line 131 is connected between a bottom of the processing chamber 102 and a gas exhaust unit 135. The gas exhaust unit 135 is provided with a vacuum pump (air pump), such as a turbo molecular pump, and evacuates the processing chamber 102 to a predetermined reduced pressure level (for example, 0.67 Pa or lower). Additionally, a gate valve 132 is installed at a sidewall of the processing chamber 102.

Further, a first high frequency power supply 140 is electrically connected via a first matching unit 141 to the upper electrode 121. Furthermore, a low pass filter (LPF) 142 is connected to the upper electrode 121. The first high frequency power supply 140 has a frequency ranging from 50 to 150 MHz. By applying a high frequency power in such a range, a plasma of high density in a desired dissociation state can be generated within the chamber 102, which makes it possible to execute a plasma etching under a pressure lower than that in conventional cases. The frequency of the first high frequency power supply 140 preferably ranges from 50 to 80 MHz. Typically, its frequency is 60 MHz or thereabouts.

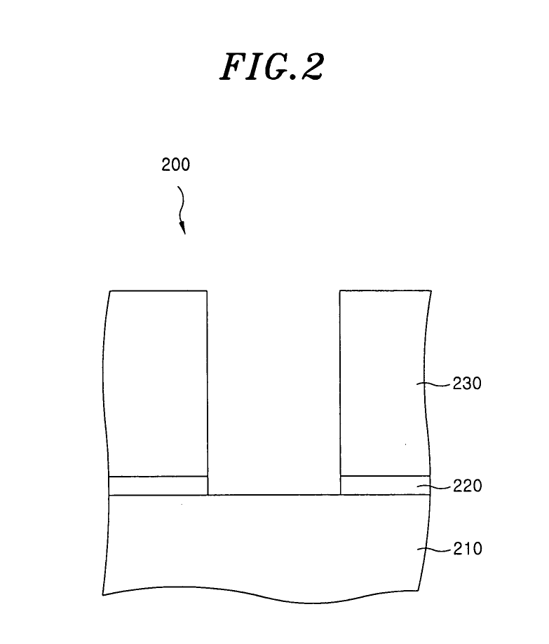

A second high frequency power supply 150 is connected via a second matching unit 151 to the susceptor 105 acting as the lower electrode. The second high frequency power supply 150 has the frequency ranging from several hundred KHz to less than twenty MHz. By applying a power of a frequency in such a range, a proper ionic action can be facilitated without causing any damage on the wafer W to be processed. Typically, the frequency of the second high frequency power supply 150 is, e.g., 13.56 MHz as shown in FIG. 2 or 2 MHz.

Next, an etching target film, on which an etching process is performed by using the etching apparatus 100, will be described with reference to FIG. 2. Herein, an oxide film formed on the wafer W is etched by using a resist including an alicyclic acrylate resin and/or an alicyclic methacrylate resin as a mask. Specifically, the etching process is performed on a film structure 200 shown in FIG. 2. The film structure 200 includes a silicon oxide film (SiO₂ film) 210 as the etching target film formed on the wafer W, an antireflection film 220 formed on the silicon oxide film 210 and an ArF photoresist film 230 formed on the antireflection film 220. The ArF photoresist film 230 is the one formed on the silicon oxide film 210 via the organic antireflection film 220 before the etching process and then patterned in a predetermined pattern including, e.g., openings or the like, by an exposure process and a developing process.

The etching target film is not limited to the silicon oxide film and the present invention can be applied to an oxide film (an oxygen compound film) such as TEOS, BPSG, PSG, SOG, a thermal oxide layer, HTO, FSG, an organic silicon oxide film, CORAL (Novellus system Inc.) or the like; a low dielectric organic insulating film; a metal film; a metal compound film or the like.

Further, as for the resist including the alicyclic acrylate resin and/or the alicyclic methacrylate resin, the present invention can be applied to an ArF photoresist film, for example. The ArF photoresist film do not have a benzene ring for absorbing a laser beam having a wavelength of 193 nm and thus can be exposed to an ArF excimer laser having a wavelength of 193 nm. The benzene ring is used in a KrF photoresist or the like due to its high plasma resistance. Since, however, the ArF photoresist film does not contain a resin having such a benzene ring, there occurs a problem of a surface roughness of a resist film or striations in case an etching process is performed by using the ArF photoresist film as the mask. However, in accordance with the preferred embodiment of the present invention, the generation of striations can be advantageously prevented even when the ArF photoresist film is used as the mask in performing the etching process.

Hereinafter, an etching process using the etching apparatus 100 will be described. In order to perform the etching process, a gate valve 132 is opened first so that a wafer W can be loaded into the processing chamber 102 and then mounted on the electrostatic chuck 111. Next, the gate valve 132 is closed and an inner space of the processing chamber 102 is depressurized by the gas exhaust unit 135. Thereafter, a valve 128 is opened, so that a processing gas can be introduced from the processing gas supply source 130 and a pressure in the processing chamber 102 can be set at a predetermined level. In this state, a predetermined high frequency power is supplied from each of the first and the second high frequency power supply 140 and 150, so that the processing gas becomes a plasma, which in turn acts on the wafer W.

In the meantime, before or after the high frequency powers are supplied, a DC power is applied from the DC power supply 113 to the electrode 112 in the electrostatic chuck 111 to electrostatically adsorb the wafer W thereon. Further, during the etching process, a coolant (chiller) whose temperature is set at a predetermined level is applied to the temperature control medium channel 107 to cool the susceptor 105. At the same time, by supplying a heat transfer medium (e.g., a backside gas such as a He gas or the like) having a predetermined pressure to a backside of the wafer W, a surface temperature of the wafer W is controlled at a predetermined level. In the preferred embodiment of the present invention, the etching process is performed by setting a surface temperature of the wafer W at 20° C. or less, thereby solving drawbacks otherwise generated on the wafer W in the prior art etching process.

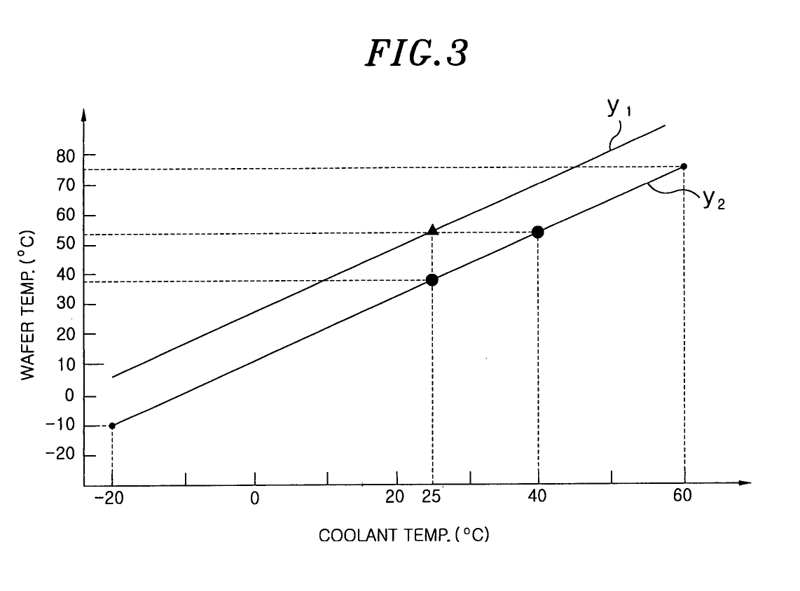

FIG. 3 illustrates a relationship between a temperature of the coolant (a temperature of the lower electrode) and a surface temperature of the wafer W, wherein the surface temperature of the wafer W is measured when the temperature of the coolant is, e.g., −20° C., 25° C., 40° C. and 60° C. As the temperature of the coolant is lowered, the surface temperature of the wafer W decreases, nearly in proportion to the coolant temperature, as illustrated in FIG. 3.

Since, however, a cooling efficiency varies depending on methods for adsorbing the wafer W, there may be a deviation (variation) in the relationship between the temperature of the coolant and the surface temperature of the wafer W depending on the wafer W adsorbing methods. For example, in case of electrostatically adsorbing and maintaining the wafer W while supplying a backside gas to the susceptor 105, the surface temperature of the wafer W is about 55° C. (triangular data point ▴) when the temperature of the coolant is 25° C., as illustrated in FIG. 3.

On the other hand, when adhering the wafer W to the electrostatic chuck 111 by grease under the same condition, the surface temperature of the wafer W is about 40° C., which indicates a decrease of the temperature. This is because the cooling efficiency is improved due to an enhancement of an adsorptive power of the wafer W on the electrostatic chuck 111 achieved by employing the grease.

Therefore, in case of using the grease, the temperature of the coolant is in proportion to the surface temperature of the wafer W as illustrated by a straightline y2 passing through data points represented by circles ●. In case the grease is not used, the relationship therebetween is believed to be in a proportional relationship as depicted by a straight line y1 passing through the data point represented by the triangular ▴.

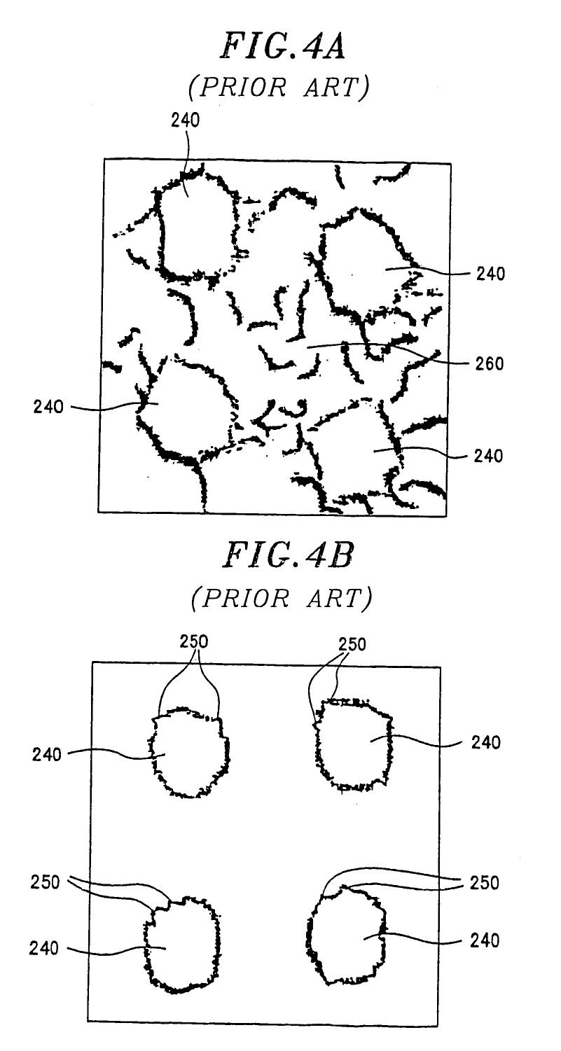

Hereinafter, in comparison with a case of the present invention, a case suffering from drawbacks generated on the wafer W by the etching process will be described with reference to FIGS. 4A and 4B. FIGS. 4A and 4B provide results of an experiment in which an etching process was performed by setting a temperature of the coolant (a temperature of the lower electrode) at 25° C. so that a surface temperature of the wafer can be about 40° C. (in case of using the grease) under a first basic etching condition described below

[First Basic Etching Condition]

Processing gas: C₄F₆+Ar+O₂

Processing gas flow rate ratio: C₄F₆/Ar/O₂=14 sccm/500 sccm /17 sccm

Pressure in the processing chamber: 20 mTorr

High frequency power applied to the upper electrode: 1600 W

High frequency power applied to the lower electrode: 800 W

Gap between the electrodes: 35 mm

Temperature (upper electrode/sidewall): 60° C./50° C.

Backside gas pressure (center/edge): 3 Torr/3 Torr

Etching time: 60 seconds

FIG. 4A shows a state of a top surface of the ArF photoresist film 230 after etching, and FIG. 4B presents a state of a top surface of the silicon oxide film 210 after removing the ArF photoresist film 230 and the antireflection film 220 by ashing or the like. It can be seen from FIG. 4A that a surface roughness 260 was incurred on the ArF photoresist film 230. If the surface roughness 206 is generated on the ArF photoresist film 230 as shown, a shape of an opening is changed as the etching progresses, resulting in drawbacks in that an etched hole or groove may not be formed to have a designed shape. Accordingly, the surface roughness 260 of the ArF photoresist film 230 needs to be prevented. In accordance with the etching method of the preferred embodiment, which will be described later, the surface roughness 260 can be prevented.

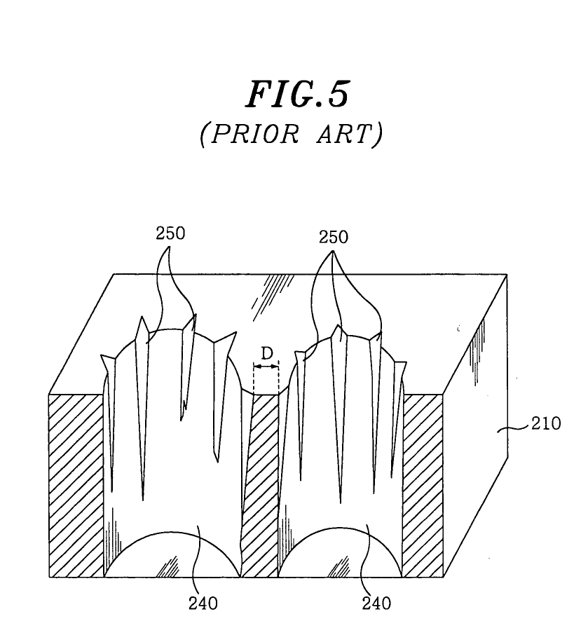

Referring to FIG. 4B, it can be seen from the irregularities in the shape of the openings that striations 250 are generated. The term, striations 250 used herein denotes vertically striped cutouts (or grooves) formed on inner surfaces of holes 240 by etching, as illustrated in FIG. 5. If such striations 250 are generated, a distance D between the holes 240 becomes narrow. Therefore, if a semiconductor device is manufactured in such state, drawbacks such as shorts or the like are incurred. For the reason, the generation of the striations 250 needs to be prevented. In accordance with the etching method of the preferred embodiment, which will be described later, the striations 250 can be prevented.

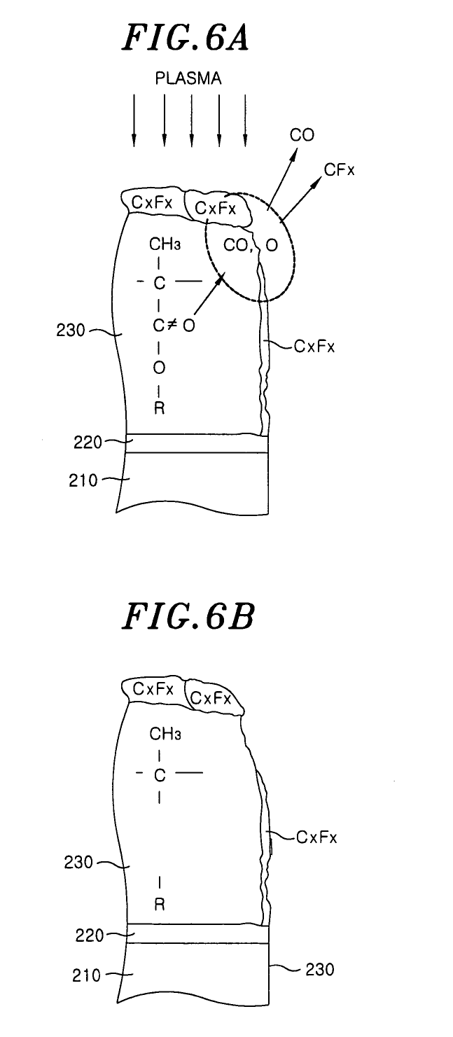

One of the plausible causes of the generation of the above-described striations 250 will be described with reference to FIGS. 6A and 6B. In case an etching process is performed by using a CF-based gas such as a C₄F₆ gas or the like as a processing gas and by employing a resist containing oxygen O such as the ArF photoresist film 230 or the like as a mask, reaction by-products (CxFx) generated by the etching process are adhered to and accumulated on a surface (a top surface and/or a side surface) of the ArF photoresist film 230. In case such reaction by-products (CxFx) are adhered to an entire surface of the ArF photoresist film 230, the reaction by-products (CxFx) serves as a protective layer of the ArF photoresist film 230, thereby preventing the surface roughness or the striations.

However, as illustrated in FIG. 6A, the oxygen bond present in the ArF photoresist film 230 is cleaved by a plasma of the CF-based gas to make free oxygen O or the like, which then reacts with CF-based radicals at the surface of the ArF photoresist film 230, thereby being discharged as, e.g., CO and CFx. In portions where such phenomenon occurs, the discharge of CO and CFx resulting from the reaction of oxygen contained in the ArF photoresist film 230 with the CF-based gas becomes predominant over the adhesion of the reaction by-products (CxFx) by the plasma of the CF-based gas, so that the reaction by-products (CxFx) are hardly adhered to the ArF photoresist film 230. Especially, such phenomenon is more noticeable at a shoulder portion having a low selectivity against the resist among the surface of the ArF photoresist film 230.

Further, among the surface of the ArF photoresist film 230, portions where the reaction by-products (CxFx) are not adhered are gradually sputtered as the etching process progresses, so that the ArF photoresist film 230 only at such portions is lost as illustrated in FIG. 6B, which is considered to cause the striations 250.

Accordingly, in the preferred embodiment of the present invention, the etching process is performed by lowering a surface temperature of the wafer W in order to avoid the aforementioned surface roughness of the ArF photoresist film 230 and the striations 250 (vertically-striped cutouts).

In other words, by performing the etching process while maintaining the low surface temperature of the wafer W, the adhesion of the reaction by-products (CxFx) prevails over the discharge of CO and CFx resulting from the reaction of oxygen or the like that are contained in the ArF photoresist film 230 with the CF-based gas, so that the reaction by-products (CxFx) can be readily adhered to the ArF photoresist film 230. Further, by setting the surface temperature of the wafer W at a low level, it is possible to retard a cleavage reaction of the oxygen binding present in the ArF photoresist film 230 due to the plasma of the CF-based gas. Accordingly, the surface roughness 260 and the striations 250 (vertically-striped cutouts) of the ArF photoresist film 230 can be avoided by the preferred embodiment of the present invention.

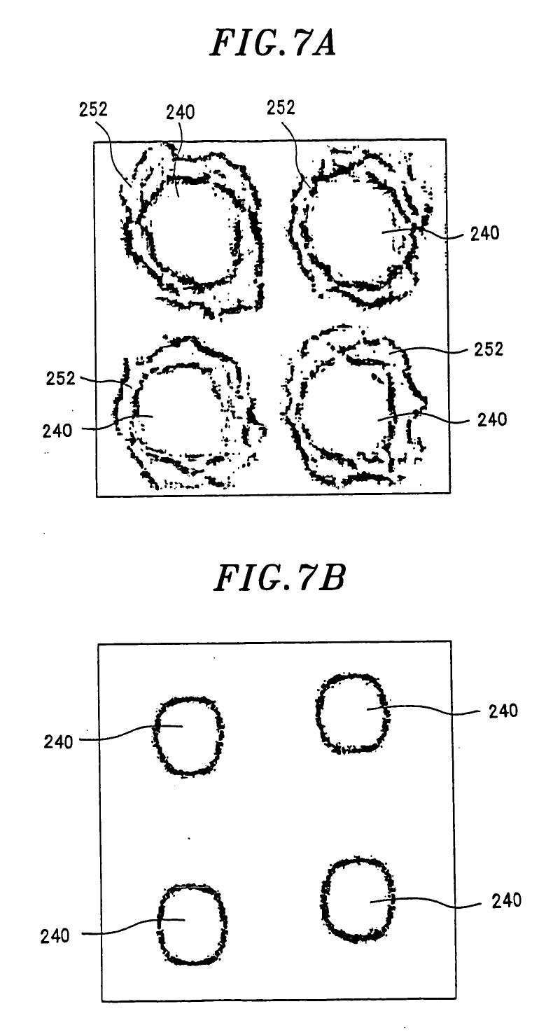

Hereinafter, there will be described with reference to FIGS. 7A and 7B results of an experiment in which the etching process was performed by setting the surface temperature of the wafer W at a low level based on the aforementioned principle. FIGS. 7A and 7B depict results of an experiment in which the etching process was performed by setting a temperature of a coolant (a temperature of the susceptor 105 functioning as the lower electrode) at −20° C. to obtain a surface temperature of the wafer W of about −10° C. (in case of using the grease) under the aforementioned first basic etching condition described above.

FIG. 7A shows a state of the top surface of the ArF photoresist film 230 after etching, and FIG. 7B illustrates a state of the top surface of the silicon oxide film 210 after removing the ArF photoresist film 230 and the antireflection film 220 by ashing or the like. As shown in FIG. 7A, the surface roughness is not observed on the ArF photoresist film 230. Further, circumferential portions 252 being observed around the holes 240 formed by the etching process correspond to shoulder portions of the ArF photoresist film 230. Furthermore, it can be seen from FIG. 7B that the openings 240 attain a round (smooth) shape without irregularities, which indicates that the striations 250 are not generated. That is, by performing the etching process by setting the surface temperature of the wafer W at a low level, the surface roughness of the ArF photoresist film 230 and the striations (vertically-striped cutouts) 250 can be prevented.

Moreover, it was formed that an etching rate of the silicon oxide film 210 and a selectivity thereof against the ArF photoresist film 230 can be improved by performing the etching process by setting the surface temperature of the wafer W at a low level. Table 1 below shows the results of an experiment in which an etching process was performed by setting a temperature of a coolant (a temperature of the susceptor 105 constituting the lower electrode) at 60° C., 40° C., 25° C. and −20° C., under the first basic etching conditions. Surface temperatures of the wafer W (in case of using grease) corresponding thereto was about 75° C., 55° C., 40° C. and −10° C., respectively.

TABLE 1

| | | | | |
|---|---|---|---|---|
| Temperature of coolant | 60 | 40 | 25 | −20 |
| (temperature of lower | | | | |
| electrode) [° C.] | | | | |
| Wafer surface temperature | about | about | about | about |
| [° C.] | 75 | 55 | 40 | −10 |
| Etching rate [nm/min] | 332 | 337 | 350 | 410 |
| Selectivity | 6.2 | 7.1 | 7.0 | 22.3 |

The etching rate and the selectivity in Table 1 represent an etching rate of the silicon oxide film 210 and a selectivity thereof against the ArF photoresist film 230, respectively. It can be seen from Table 1 that the etching rate and the selectivity are improved as a temperature of a coolant (a temperature of the lower electrode) is lowered, i.e., as the wafer surface temperature decreases.

As described above, the surface roughness 260 and the striations 250 can be prevented and, further, the etching rate and the selectivity can be improved as the surface temperature of the wafer W is lowered. In practice, it is preferable to set the surface temperature of the wafer W to be lower than or equal to 20° C. and, more preferably, lower than or equal to 0° C.

Lowering a surface temperature of the wafer W can be achieved through the use of an heat dissipation mechanism and/or a heat sink mechanism. Decreasing a temperature of a coolant (a temperature of the lower electrode) supplied to the temperature control medium channel 107 can be exemplified as the heat dissipation mechanism for example. In this case, a cooling efficiency can be improved by enhancing an adsorptive power of the wafer W.

In order to enhance the adsorptive power of the wafer W, the grease may be applied on a backside of the wafer W as described above to thereby enhance the adhesion between the wafer W and the surface of the electrostatic chuck 111. In addition, the backside of the wafer W may be finished in advance to be of a mirror surface or the wafer W is firmly pressed with a clamp.

Further, by forming in advance a SiN film on the backside of the wafer W, static electricity induced by the electrostatic chuck 111 can be easily collected at the boundary between the SiN film of the wafer W and a wafer substrate, thereby enhancing the adsorptive power. In such a case, by providing the wafer substrate with a stacked structure of SiN and SiO₂, the static electricity can be more readily collected and, accordingly, the adsorptive power can be further enhanced.

In case an electrostatic chuck of a Johnson-Rahbek type is used as the electrostatic chuck 111, a material of an electrode of the electrostatic chuck 111 may be modified so that a leakage current functioning to contribute to the adsorptive power can flow even under the low temperature condition. By doing so, it is possible to improve the adsorptive power under the low temperature condition. In the electrostatic chuck of the Johnson-Rahbek type, a wafer mounting surface thereof is, e.g., coated with a dielectric film layer, which is made of a dielectric substance such as an inorganic material, e.g., ceramic or the like, or heat resistant resin, e.g., polyimide resin or the like, and the dielectric film layer is used as a electrostatic chuck. That is, if a DC voltage is applied from one side of the dielectric film layer having a film thickness of d and a permittivity of ε, positive and negative electric charges satisfying the equation of Q=εV/d per unit area are accumulated on both sides of the dielectric film layer. Then, the wafer W is adsorbed via the dielectric film layer by the Coulomb force of the electric charges. However, in case the dielectric film layer is made of a material having a resistivity smaller than 1×10¹² Q•cm, a small amount of current flows in the dielectric film layer, so that the electric charges are accumulated on a surface of the dielectric film layer. As a result, the apparent “d” term in the charge expression becomes very small and a strong adsorptive power can be obtained. Thus, in order to obtain the strong adsorptive power under the low temperature condition, it is preferable to use a material having a resitivity smaller than 1×10¹² Q•cm as a material for an electrode, i.e., the dielectric film layer. As a result, it is possible to enhance the adsorptive power of the wafer W at a low temperature.

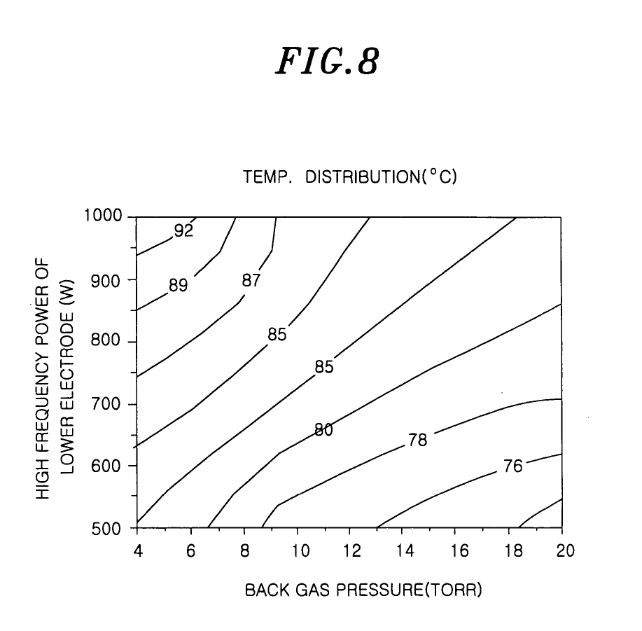

Exemplified as the heat sink mechanism, can be lowering a second high frequency power applied to the susceptor 105 of the lower electrode and/or increasing a pressure of a backgas, e.g., a He gas, supplied to a backside of the wafer W. FIG. 8 illustrates a distribution of a surface temperature of the wafer W in case of varying the second high frequency power applied to the lower electrode and the backgas pressure. Referring to FIG. 8, as the second high frequency power applied to the lower electrode decreases and the backgas pressure increases, the surface temperature of the wafer W is lowered.

The etching process is performed while controlling the surface temperature of the wafer to be lower than or equal to about 20° C. by using such heat dissipation mechanism or heat sink mechanism or a combination thereof. Accordingly, the etching process under the low temperature condition can be achieverd.

Hereinafter, a second preferred embodiment of the present invention will be described with reference to the drawings. In the second preferred embodiment, an etching process is performed on an alternative etching target film by the etching apparatus 100. That is, an etching target film in the first preferred embodiment is a silicon oxide film (SiO₂ film), whereas that in the second preferred embodiment is, e.g., a low-k insulating film including silicon (Si), oxygen (O) and carbon (C) atoms. Such low-k dielectric insulating film includes, e.g., a carbon doped oxide (CDO) film. In the second preferred embodiment, a CDO film (for example, Aurola (brand name) of ASM International N.V.) is used as the etching target film. Further, a dielectric constant (k value) of the CDO film ranges from 2.4 to 2.6.

In the second preferred embodiment, the above-described CDO film formed on the wafer W is etched by using a resist including an alicyclic acrylate resin and/or an alicyclic methacrylate resin, e.g., an ArF photoresist, as the mask. In this case, a specific film structure is equal to the film structure 200 illustrated in FIG. 2 except that the silicon oxide film (SiO₂ film) 210 as an etching target film is replaced by the CDO film.

In this case, an etching process was performed by lowering a temperature of a coolant (a temperature of the lower electrode) down to, e.g., 0° C. and 30° C. under the second basic etching condition. When the temperature of the coolant was set at 0° C., the surface temperature of the wafer W was about 15° C. and when the temperature of the coolant is set at −30° C., the surface temperature of the wafer W was about −9° C.

[Second Basic Etching Condition]

Processing gas: C₄F₈+CO+N₂

Processing gas flow rate ratio: C₄F₈/CO/N₂=6 sccm/30 sccm/460 sccm

Pressure in the processing chamber: 100 mTorr

High frequency power applied to the upper electrode: 400 W

High frequency power applied to the lower electrode: 1500 W

Gap between the electrodes: 35 mm

Temperature (upper electrode/sidewall): 60° C./60° C.

Backside gas pressure (center/edge): 15 Torr/40 Torr

Etching time: 30 seconds

The etched shape obtained by the above etching process showed that the surface roughness and the striations (vertically-striped notches) 250 are improved as the temperature of the coolant (the temperature of the lower electrode) decreases. The ArF photoresist film does not contain a resin containing a benzene ring having a high plasma resistance used in, e.g., a KrF photoresist film. Therefore, in case the ArF photoresist film 230 is used as a mask, the striations 250 are generated by the etching process even when an etching target film is the COD film. However, in case the etching process is performed by setting the surface temperature of the wafer W at a low level as in the second preferred embodiment, the surface roughness of the ArF photoresist film 230 and the striations (vertically-striped notches) 250 can be prevented even when the etching target film is the CDO film.

Further, in case the etching process was performed by setting the temperature of the coolant (the temperature of the lower electrode) to be 0° C. under the second etching conditions, an etching rate of the COD film with respect to the ArF photoresist film was 444 nm/min near a center of the wafer W and 452 nm/min near an edge thereof. Further, a selectivity of the CDO film against the ArF photoresist film was 6.9 near the center of the wafer W and 15.1 near the edge thereof.

Furthermore, in case the etching process was performed by setting the temperature of the coolant (the temperature of the lower electrode) to be −30° C. under the second etching conditions, an etching rate of the COD film with respect to the ArF photoresist film was 620 nm/min near a center of the wafer W and 616 nm/min near an edge thereof. Moreover, a selectivity of the CDO film against the ArF photoresist film was 17.2 near the center of the wafer W and 13.4 near the edge thereof.

It can be seen from the results of the above experiments that the etching rate and the selectivity are improved as the temperature of the coolant (the temperature of the lower electrode) is lowered, i.e., as the wafer surface temperature decreases even in a case where the CDO film is used as an etching target film. Moreover, the heat sink mechanism and the heat dissipation mechanism used in the first embodiment are not used in this embodiment.

An etching apparatus which can be employed in the present invention is not limited to the parallel plate plasma etching apparatus and the present invention can be applied to a helicon wave plasma etching apparatus, an inductively coupled plasma etching apparatus or the like.

Etching a target film may be carried out in two steps, i.e., a main etching for etching the etching target film until an underlayer thereof is exposed, and then an over etching for etching the residual etching target film. The present invention can be applied to the main etching as well as the over etching. A surface roughness of a resist film or the like can also be avoided during the over etching by lowering a surface temperature of the wafer W, so that the over etching can be effectively performed by employing the present invention.

While the invention has been shown and described with respect to the preferred embodiment, it will be understood by those skilled in the art that various changes and modifications may be made without departing from the spirit and scope of the invention as defined in the following claims.

What is claimed is:

1. An etching method for performing a plasma etching process on an etching target film formed on an object to be processed in an airtight processing chamber by generating a plasma of a processing gas introduced into the processing chamber by using a resist as a mask, the resist including an alicyclic acrylate resin, an alicyclic methacrylate resin, or a combination thereof,
wherein the plasma etching process is performed while maintaining a surface temperature of the object under a temperature condition of about 20° C. or less.

2. The etching method of claim 1, wherein the plasma etching process is performed while maintaining a surface temperature of the object under a temperature condition of about 0° C. or less.

3. The etching method of claim 1, wherein the etching target film is a low-k insulating film containing silicon (Si), oxygen (O) and carbon (C) atoms.

4. The etching method of claim 1, wherein the surface temperature of the object to be processed is lowered by using a heat dissipation mechanism.

5. The etching method of claim 4, wherein the heat dissipation mechanism includes a cooling unit for cooling the object to be processed by a coolant, and the surface temperature of the object to be processed is controlled at about 20° C. or less by lowering a temperature of the coolant.

6. The etching method of claim 4, wherein the heat dissipation mechanism includes an adsorptive holding unit for adsorptively holding the object to be processed, and the surface temperature of the object to be processed is lowered by enhancing an adsorptive power of the adsorptive holding unit.

7. The etching method of claim 6, wherein the adsorptive power is enhanced by finishing a surface of the object to be processed to be of a mirror surface, the surface being in contact with the adsorptive holding unit.

8. The etching method of claim 6, wherein the adsorptive power is enhanced by adopting a material of the adsorptive holding unit to allow an amount of leakage current flowing therethrough to be controlled under the temperature condition.

9. The etching method of claim 1, wherein the surface temperature of the object is lowered by a heat sink mechanism.

10. The etching method of claim 9, wherein surface temperature lowering of the object by the heat sink mechanism is carried out by controlling a high frequency power applied to an electrode disposed in the processing chamber to generate a plasma and a pressure of a backgas supplied to a backside of the object.

11. An etching apparatus for performing a plasma etching process on an etching target film formed on an object to be processed in an airtight processing chamber by generating a plasma of a processing gas introduced into the processing chamber by using a resist as a mask, the resist including an alicyclic acrylate resin, an alicyclic methacrylate resin, or a combination thereof,
wherein the plasma etching process is performed while maintaining a surface temperature of the object under a temperature condition of about 20° C. or less.

12. The etching apparatus of claim 11, wherein the plasma etching process is performed while maintaining a surface temperature of the object under a temperature condition of about 0° C. or less.

13. The etching apparatus of claim 11, wherein the etching target film is a low-k insulating film containing silicon (Si), oxygen (O) and carbon (C) atoms.

14. The etching apparatus of claim 11, wherein the surface temperature of the object to be processed is lowered by using a heat dissipation mechanism.

15. The etching apparatus of claim 14, wherein the heat dissipation mechanism includes a cooling unit for cooling the object to be processed by a coolant, and the surface temperature of the object to be processed is controlled at about 20° C. or less by lowering a temperature of the coolant.

16. The etching apparatus of claim 14, wherein the heat dissipation mechanism includes an adsorptive holding unit for adsorptively holding the object to be processed, and the surface temperature of the object to be processed is lowered by enhancing an adsorptive power of the adsorptive holding unit.

17. The etching apparatus of claim 16, wherein the adsorptive power is enhanced by finishing a surface of the object to be processed to be of a mirror surface, the surface being in contact with the adsorptive holding unit.

18. The etching apparatus of claim 16, wherein the adsorptive power is enhanced by adopting a material of the adsorptive holding unit to allow an amount of leakage current flowing therethrough to be controlled under the temperature condition.

19. The etching apparatus of claim 11, wherein the surface temperature of the object is lowered by a heat sink mechanism.

20. The etching apparatus of claim 19, wherein surface temperature lowering of the object by the heat sink mechanism is carried out by controlling a high frequency power applied to an electrode disposed in the processing chamber to generate a plasma and a pressure of a backgas supplied to a backside of the object.
